(19) United States
(12) Patent Application Publication
(10) Pub. No.: US 2025/0234451 A1
(43) Pub. Date: Jul. 17, 2025

(54) PRINTED CIRCUIT BOARD ASSEMBLY

(71) Applicant: Rolls-Royce Deutschland Ltd & Co KG, Blankenfelde-Mahlow (DE)

(72) Inventors: Uwe WALTRICH, Forchheim (DE); Stanley BUCHERT, Herzogenaurach (DE)

(21) Appl. No.: 18/703,183

(22) PCT Filed: Nov. 8, 2022
(86) PCT No.: PCT/EP2022/081159

§ 371 Date: Apr. 19, 2024

(30) Foreign Application Priority Data
Nov. 9, 2021 (DE) 10 2021 129 117.8

(51) Int. Cl. H05K 1/02

(52) U.S. Cl. CPC H05K 1/0203; H05K 2201/066; H05K 2201/10598

(57) ABSTRACT

A circuit board assembly includes: a circuit board having an upper side and a lower side; at least one electrical component arranged on the lower side of the circuit board; a heat sink; and a hold-down device, wherein the hold-down device presses the circuit board against the heat sink. Furthermore, the hold-down device is configured to be spring-loaded and exert a spring force on the circuit board.

The present patent document is a § 371 nationalization of PCT Application Serial No. PCT/EP2022/081159, filed Nov. 8, 2022, designating the United States, and this patent document also claims the benefit of German Patent Application No. 10 2021 129 117.8, filed Nov. 9, 2021, which are incorporated by reference in their entireties.

### TECHNICAL FIELD

The disclosure relates to a circuit board assembly.

### BACKGROUND

The prior art includes the practice of cooling circuit board-based power electronics assemblies by pressing them against a heat sink by screwed joints, wherein the components to be cooled may be configured as surface-mounted (SMD) components (“surface-mounted device”) or as through-hole assemblies (THT=“through-hole technology”) and are seated on the underside of a circuit board. The number of screws with which the circuit board is screwed to a heat sink may be minimized so that the circuit board layout is not overly restricted by the screw connections. The stated boundary condition means that with a high number of components to be cooled on the underside of the circuit board, only a limited number of screw points are available, so that it is not possible to press components selectively onto the heat sink via assigned individual screw points.

In this case, any gap between the component to be cooled and the heat sink leads to impairment of the thermal connection of the electrical component to the heat sink. The gap between a component to be cooled and the heat sink may therefore be minimized. In the case of a plurality of components that need to be cooled, there may be gaps with different gap dimensions with respect to the heat sink, which need to be compensated. Further tolerances in the gap dimensions result from a thickness tolerance of the circuit board and local thermal deflections of the circuit board.

One known practice for compensating these height tolerances is to use heat-conducting materials. In power electronics, paste systems are used, and these are applied to the cooling surface and compensate for minimal gaps and roughness of up to 100 μm. If higher gap dimensions need to be compensated for, thermally conductive foils or so-called gap pads or gap filler materials up to a few millimeters thick are used.

To compensate for the height tolerances mentioned, it is also known to press SMD components of a circuit board against the heat sink using a hold-down construction. The higher the pressure between the heat sink and the component to be cooled, the greater the thermal conductivity and therefore the cooling effect of the heat sink.

### SUMMARY AND DESCRIPTION

The object of the present disclosure is to provide a circuit board assembly that provides a hold-down device for a circuit board that enables an effective thermal connection of a component to be cooled to a heat sink.

The scope of the present disclosure is defined solely by the appended claims and is not affected to any degree by the statements within this summary. The present embodiments may obviate one or more of the drawbacks or limitations in the related art.

The disclosure then considers a circuit board assembly that has a circuit board with a top side and an underside, at least one electrical component arranged on the underside of the circuit board, a heat sink, and a hold-down device, wherein the hold-down device presses the circuit board against the heat sink. It is intended that the hold-down device is spring-loaded and exerts a spring force on the circuit board.

The solution is based on the idea of increasing the contact pressure between the electrical component to be cooled and the heat sink by providing a spring force or providing this pressure during operation under all environmental influences. In this way, the electrical component is pressed more effectively against the heat sink by the spring force provided. This is achieved by providing a hold-down construction that makes it possible to exert spring pressure specifically on areas of the circuit board where a component to be cooled is placed against the underside. The hold-down construction may be segmented in certain configurations.

The solution makes it possible to minimize the unavoidable gap between the component to be cooled and the heat sink and, accordingly, to minimize the thickness of the required pastes or thermally conductive foils or gap pads between the components to be cooled and the heat sink. This improves the thermal conductivity between the components and the heat sink. The possibility of pressing individual components to be cooled locally against the heat sink makes it possible to cool a large number of components effectively.

The electrical component arranged on the underside of the circuit board is, for example, surface-mounted or connected to the circuit board in through-hole mounting.

For the purposes of the present disclosure, the side of the circuit board on which an electrical component to be cooled is arranged and adjoins a heat sink is referred to as the underside of the circuit board. This may be the side of the circuit board that is closer to the ground with respect to the vertical perpendicular direction. However, the circuit board and heat sink to be cooled may also be arranged in an inverted or vertical manner and accordingly point upwards or to the side, in which case, for the purposes of the present disclosure, the circuit board likewise adjoins the heat sink with its underside.

One embodiment of the disclosure provides for a two-part design of the hold-down device. The hold-down device has an upper part and a lower part, each of which is plate-shaped, for example. The lower part of the hold-down device rests against the top side of the circuit board. The upper part of the hold-down device lies against the top side of the lower part. The lower part is made of an electrical insulation material and the upper part is made of a material that has greater mechanical rigidity than the lower part, for example, stainless steel or spring steel.

In certain examples, the upper part and the lower part of the hold-down device are not necessarily separate parts. For example, embodiments of the hold-down device provide for the upper part and the lower part to be combined in one overall part, for example, by providing a metal part partially overmolded with plastic. Such a connection is made in the edge areas, for example, whereas the central areas are separated.

The aforementioned two-part design of the hold-down device provides that no high point loads are introduced into the circuit board by the spring forces, as the spring forces are distributed over the surface by the lower part. This is important because the material of the circuit board is comparatively soft and locally high point loads may damage the circuit board. The aforementioned two-part design also provides that the electrical insulation of the circuit board is not impaired by the spring forces introduced because the lower part is made of an electrically insulating material.

In the two-part version of the hold-down device with an upper part and a lower part, there are three variants for providing spring force. A first variant provides for the upper part to be resilient. A second variant provides for the lower part to be resilient. A third variant provides for the hold-down device to also include separate spring elements that apply a force to the upper part and the lower part relative to each other. These three variants are examined in greater detail below.

First of all, the case is considered in which the upper part of the hold-down device is resilient and exerts a spring force on the lower part. The lower part in turn presses on the circuit board. For this purpose, one embodiment provides for the upper part to be resilient overall. This may be realized in many different ways. In one embodiment, the upper part is designed in the form of a plate that is mechanically rigid in an edge area and elastic in a central area, for example, by bulges arranged in a matrix and directed towards the lower part and/or by a reduced thickness of the upper part in the elastic area. The mechanically rigid edge area is screwed to the circuit board and the heat sink using screws. The elastic middle section, on the other hand, has a resilient design.

According to an alternative embodiment, the upper part has individual spring elements that are attached to or integrated into a firmly clamped rigid plate of the upper part and provide a spring effect in the direction of the lower part. In this embodiment, the upper part is not resilient as a whole (wherein it forms a spring element), but includes several local spring elements that exert spring forces on the lower part at several points.

In the case in which the lower part of the hold-down device is resilient, embodiments provide that spring elements are attached or formed in receiving openings of the lower part and rest resiliently against the upper part and in so doing exert a spring force on the circuit board. The spring elements arranged in the receiving openings are formed, for example, by an elastic insulating material.

In the case in which separate spring elements are intended to provide a spring force and act on the upper part and the lower part relative to each other with a relative force that presses the lower part against the circuit board, one embodiment provides that such separate spring elements are arranged in receiving openings in the lower part and/or in receiving openings in the upper part. The spring elements may be inserted loosely into such recesses. For example, they are designed as flat metal spring constructions, such as disk springs, and act as compression springs that attempt to separate the two parts of the hold-down device from each other.

In all three variants mentioned, one embodiment provides that the lower part of the hold-down device is segmented and has segments that have a different thickness and/or a different material compared to other areas of the lower part. In particular, at least some of the surface-mounted electrical components arranged on the underside of the circuit board may each be assigned a separate segment of the lower part of the hold-down device, wherein the separate segment is adjacent to the area on the top side of the circuit board which is opposite the area on the underside of the circuit board on which the respective electrical component is located. This makes it possible to press the surface-mounted electrical component assigned to the segment to be cooled against the heat sink by applying a spring force to the respective segment.

The lower part may have segments that have a reduced thickness and each form an upward-facing receiving opening. Depending on the design of the hold-down device, a spring element connected to or integrated into the upper part may protrude into such a receiving opening or a separate spring element may be inserted into such a receiving opening.

If the lower part is resilient, one embodiment provides that the lower part has segments that are formed by filled receiving openings, wherein the receiving openings are filled with an insulating material which is intended and designed to provide a spring force via its material properties and/or its geometry. The receiving openings may extend over the entire thickness of the lower part. In such an embodiment, the segment as a whole is designed as a spring element, specifically as a spring element made of a non-conductive insulating material.

Segmentation of the lower part allows a separate spring element to be assigned to each segment of the lower part to which an electrical component is assigned, which presses the lower part against the circuit board in the area of the respective segment, wherein local warping of the circuit board is generated, which presses the assigned electrical component locally against the heat sink with a minimum gap.

The spring elements used to generate a spring force may be configured as spring constructions, in particular flat spring constructions and/or by elastic properties of a material used. Examples of this are metal spring constructions such as disk springs. Other examples are elastic materials, in particular elastic plastics. For example, the spring elements are designed as plastic inserts made of an elastic plastic. Their spring function may additionally be improved by a resilient geometry.

### BRIEF DESCRIPTION OF THE DRAWINGS

The disclosure is explained in greater detail below by a plurality of embodiments and with reference to the figures of the drawing, in which:

FIG. 1 shows an embodiment of a circuit board assembly including a circuit board, a heat sink, and a hold-down device, wherein the hold-down device includes an upper, resilient part and a lower part made of plastic, wherein the upper part presses the lower part against the circuit board.

FIG. 2 shows a further embodiment of a circuit board assembly including a circuit board, a heat sink, and a hold-down device, wherein the hold-down device includes an upper, firmly clamped part, a lower part made of plastic, and separate spring elements that press the lower part against the circuit board.

FIG. 3 shows a further embodiment of a circuit board arrangement including a circuit board, a heat sink, and a hold-down device, wherein the hold-down device includes an upper part and a lower part made of plastic and spring elements made of an elastic material are integrated into the lower part.

FIG. 4 shows a circuit board arrangement with a circuit board, a heat sink, and a hold-down device according to the prior art.

FIG. 5 shows a further circuit board arrangement with a circuit board, a heat sink, and a hold-down device according to the prior art.

### DETAILED DESCRIPTION

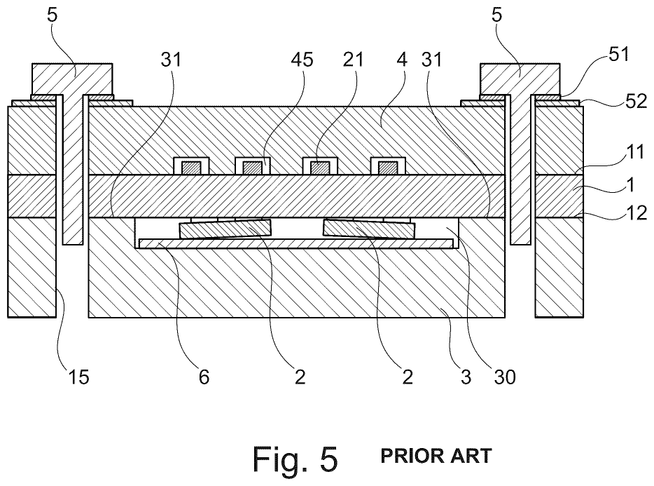

For a better understanding of the background of the present disclosure, circuit board assemblies according to the prior art are first of all described on the basis of FIGS. 4 and 5.

FIG. 4 shows a circuit board assembly, which includes a circuit board 1 and a heat sink 3. The circuit board 1 is made of a multiplicity of circuit board layers (not shown separately), which are arranged one above the other. In this case, an uppermost circuit board layer forms an upper side 11 of the circuit board 1 and a lowermost circuit board layer forms an underside 12 of the circuit board 1.

Electrical components or parts 2 are arranged on the underside 12 of the circuit board 1. The connection to the circuit board 1 is made, for example, via surface mounting, wherein the components 2 are SMD components. This is however to be understood merely as an example. In addition, electrical components may also be arranged on the upper side 11 of the circuit board 1. Of particular interest in the present context, however, are the components 2 arranged on the underside 12, which are active components (for example, components or modules of power electronics), which require cooling by the heat sink 3. For this purpose, the heat sink 3 has a recess 30, into which the components 2 to be cooled project, wherein the components 2 to be cooled come into direct thermal contact with the heat sink 3 on their underside.

In this case, it is disadvantageous if there is a gap between the respective component 2 and the heat sink 3 because such a gap impairs the thermal connection to the heat sink 3. On the other hand, such gaps may hardly be avoided, especially if a large number of components 2 to be cooled are arranged on the underside 12 of the circuit board 1.

To improve the thermal connection, a gap pad 6 may be arranged between the components 2 to be cooled and the heat sink 3. The maximum gap dimension between the components 2 and the heat sink 3 is decisive for the design of the gap pad 6 with regard to its material and thickness.

The circuit board 1 is screwed to the heat sink 3 by metal screws 5. The metal screws 3 are screwed into through-holes 15, which extend from the circuit board 1 into the heat sink 3. The metal screws 3 rest on the upper side 11 of the circuit board 1 via a washer 51 and metallization 52. They provide a pressure force with which the circuit board 1 is pressed against the heat sink 3. In particular, they provide the pressure force with which the components 2 to be cooled, which are arranged on the underside 2 of the circuit board, are pressed against the surface of the heat sink 3 in order to provide a good thermal transition.

The heat sink 3 may have numerous configurations. For example, the heat sink 3 is made of a metal such as, for example, aluminum or an aluminum alloy and has cooling surfaces (not shown separately).

To improve the thermal contact between the components 2 to be cooled and the heat sink 3, hold-down devices may be used to press the circuit board against the heat sink. Such a hold-down device is illustrated in FIG. 5. The basic structure is the same as in FIG. 4. Above the circuit board 1 there is also a hold-down device 4, which is a plate that has recesses 45 on its underside for holding components 21 arranged on the top side of the circuit board 1 and which otherwise lies flat against the top side of the circuit board 1. The hold-down device 4 may be used to standardize the contact pressure over the surface of the circuit board 1. However, the hold-down device 4 may only provide a counterforce to deflections and height tolerances up to the height of a heat sink stop, which in FIG. 5 is formed by the surfaces 31 that delimit the recess 30 in the heat sink 3. Gaps and gap differences caused by tilted components 2, fluctuations in the circuit board thickness or uneven cooling surfaces cannot be improved by the hold-down device 4.

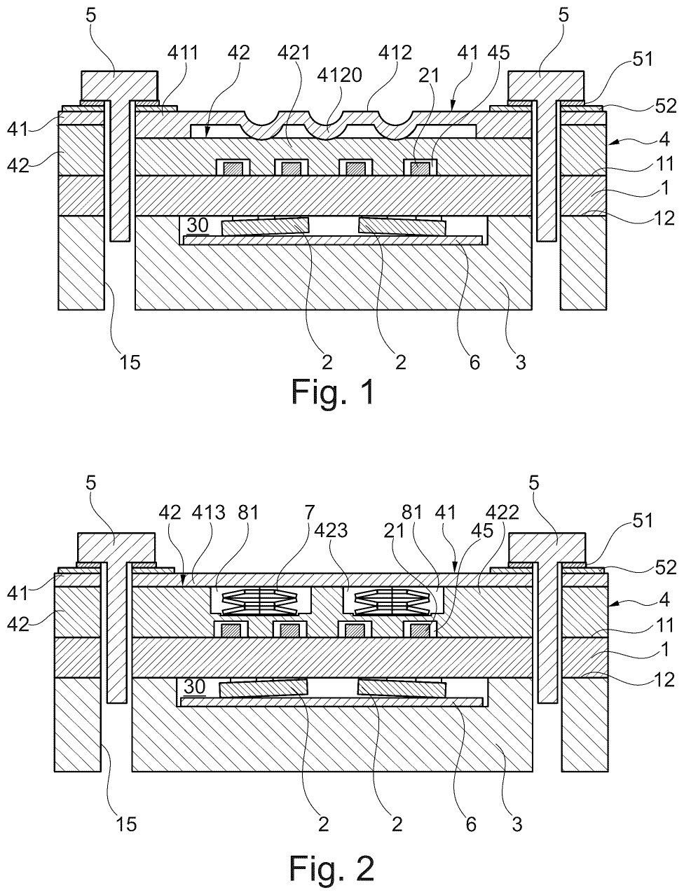

FIG. 1 shows an embodiment of a circuit board assembly, which includes a circuit board 1, a heat sink 3, and a hold-down device 4. The circuit board 1 has a top side 11 and an underside 12, wherein active components 2 are arranged on the underside 12, which protrude into a recess 30 of the heat sink 3 and are thermally coupled to the heat sink 3 via a gap pad 6 or another heat-conducting material. Screws 5 are used to generate a contact pressure that presses the hold-down device 4 against the circuit board 1 and the circuit board 1 against the heat sink 3. In this respect, reference is made to the description of FIGS. 4 and 5.

According to the embodiment in FIG. 1, the hold-down device 4 is formed in two parts. The hold-down device 4 includes an upper part 41 and a lower part 42, both of which are plate-shaped and form flat surfaces that run parallel to each other, at least in some areas. The lower part 42 is made of a plate 421, which lies flat against the top side 11 of the circuit board 1. The lower part 42 forms recesses 45 in areas in which components 21 are arranged on the top side 11 of the circuit board 1.

The upper part 41 is made of a mechanically rigid material, for example, stainless steel or spring steel. The upper part 41 has greater mechanical rigidity than the lower part 42.

The lower part 42 includes a plate 421 made of an electrically insulating material, for example a plastics material. An insulating material in the sense is any non-conductor and thus any material, the electrical conductivity of which at 20° C. is less than 10⁻⁸ S·cm⁻¹ (or which has a specific resistance of over 10⁸ Ω·cm). Here, “S” is the unit of measure of the electrical conductivity. By forming the lower part 42 with an insulating material, the lines and components of the electrical circuit board 1 are protected from the electrical potentials of the metal upper part 41.

The upper part 41 rests against the top side of the lower part 42. It is resilient overall, so that it exerts a spring force on the lower part 42. For this purpose, the upper part 41 is designed in the form of a plate, which is mechanically rigid in an edge area 411 and elastic in a central area 412. The mechanically rigid edge area 411 is clamped in the screw connection and is subjected to a contact pressure by the screw 5. The central area 412 is elastic in that it is thinner than the edge area 411 and forms a plurality of bulges or protrusions 4120, which are formed, for example, in matrix form in rows and columns in the central area 412. However, this is to be understood only by way of example. Any resilient structures may be integrated into the central area 412 of the upper part 41, which provide a spring effect.

The spring effect of the central area 412 provides a force that causes the circuit board 1 to warp, which in turn causes the components 2 on the underside 12 of the circuit board 1 to be pressed further towards the heat sink 3, reducing the existing gap. This improves the thermal connection of the components 2 to the heat sink 3.

In the embodiment of FIG. 1, the upper part 41 and the lower part 42 are designed as separate parts. However, this is not necessarily the case. For example, the lower part 42 may be connected to the upper part in the edge area 411 of the latter, in particular is molded around the edge area 411, so that both parts 41, 42 are combined in one part.

FIG. 2 shows a further embodiment of a circuit board arrangement with a resilient hold-down device 4. In the embodiment shown in FIG. 2, the hold-down device 4 is also in two parts, wherein it has an upper part 41 and a lower part 42. In this respect and with regard to the further structure of the circuit board arrangement, reference is made to the explanations for FIG. 1.

In the embodiment of FIG. 2, the upper part 41 is formed as a rigid plate 413, which is firmly clamped at its edge area by the screws 5. The plate 413 is made of stainless steel or spring steel, for example. The lower part 42 includes a plate 422 made of an insulating material.

Separate spring elements 7 are provided to provide spring force. These are designed as disk springs, wherein this is only intended as an example and other spring designs may also be used. The spring elements 7 are located in receiving openings 81, which are formed in the lower part 42. The receiving openings 81 do not extend over the entire thickness of the lower part 42, so that a layer of insulating material remains between the spring elements 7 and the top side of the circuit board 1. Because the plate 413 of the upper part 41 has a greater mechanical rigidity than the plate 422 of the lower part 42, the plate 422 is pressed against the circuit board 1 by the spring elements 7.

Here, as shown in FIG. 2, it may be provided that the lower part 42 forms segments 423 that differ from the other areas of the plate 422 by their thickness and/or their material, wherein the segments 423 in the exemplary embodiment of FIG. 2 have a smaller thickness, because they form the receiving openings 81. The individual segments 423 may each be assigned to an electrical component 2. The individual segments 423 may exert a local force on the circuit board 1 via the respective spring element 7, which leads to a local deformation of the circuit board 1 and thus to a targeted additional pressure force and gap minimization on the assigned component 2.

The embodiment of FIG. 2 may be modified in such a way that the spring elements 7 are not designed as separate spring elements but are connected to or integrated into the plate 413 of the upper part 41. In this case, the springs 7 protrude into the receiving openings 81 as components of the upper part 41 and are in contact with the lower part 42.

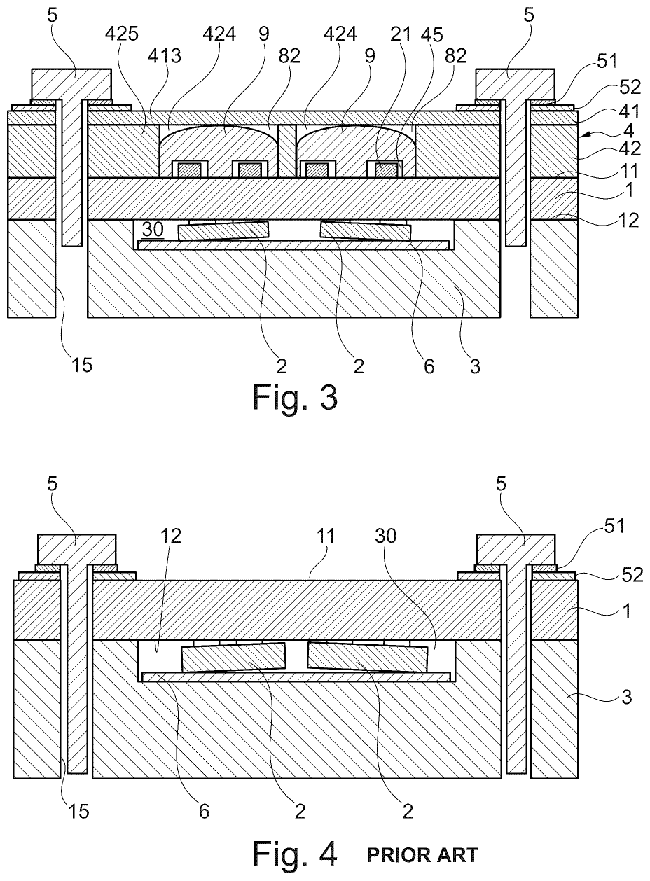

FIG. 3 shows a further embodiment of a circuit board arrangement with a two-part hold-down device 4. In this embodiment, the lower part 42 of the hold-down device 4 is resilient. As in the embodiment of FIG. 2, the upper part 41 includes a plate 413 made of a mechanically rigid material such as stainless steel. To provide a resilient formation of the lower part 42, it is segmented, wherein segments 424 are formed as filled receiving openings 82 in a plate 425 of the lower part 42. The receiving openings 82 extend here over the entire thickness of the plate 425, e.g., they are formed as continuous receiving openings 82.

The receiving openings 82 are filled with an insulating material 9 that acts as a spring element and provides a spring force via its material properties and/or its geometry. For example, it is an elastic plastics material. An additional spring effect is provided, for example, by a spherical cap which the insulation material 9 forms on its top side and with which it presses against the plate 413. Because the plate 413 of the upper part 41 has a greater mechanical rigidity than the segments 424 or the insulation material 9, the segments 424 generate a spring force that presses locally on an assigned area of the circuit board 1 and leads to a targeted additional pressure force and gap minimization in an assigned component 2.

The disclosure is not limited to the above-described embodiments and different modifications and improvements may be carried out without deviating from the concepts described here. It is furthermore to be noted that any of the features described may be used separately or in combination with any other features, provided that they are not mutually exclusive. The disclosure extends to and includes all combinations and sub-combinations of one or more features which are described here and includes these. If ranges are defined, these ranges therefore include all the values within these ranges as well as all the partial ranges that lie within a range.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A circuit board assembly comprising:
a circuit board having an upper side and an underside;
at least one electrical component arranged on the underside of the circuit board;
heat sink; and
a hold-down device that presses the circuit board against the heat sink,
wherein the hold-down device is resilient and exerts a spring force on the circuit board.

2. The circuit board assembly of claim 1, wherein the hold-down device has an upper part and a lower part,
wherein the lower part of the hold-down device rests against the upper side of the circuit board,
wherein the upper part of the hold-down device rests against a top side of the lower part of the hold-down device,
wherein the lower part of the hold-down device comprises an insulating material, and
wherein the upper part of the hold-down device comprises a material that has greater mechanical rigidity than the lower part of the hold-down device.

3. The circuit board assembly of claim 2, wherein the upper part of the hold-down device is resilient and exerts a spring force on the lower part of the hold-down device.

4. The circuit board assembly of claim 3, wherein the upper part of the hold-down device is resilient on a whole.

5. The circuit board assembly of claim 2, wherein the upper part of the hold-down device is a plate that is mechanically rigid in an edge area and elastic in a central area.

6. The circuit board assembly of claim 5, wherein the central area of the upper part of the hold-down device has bulges arranged in a matrix and directed towards the lower part of the hold-down device.

7. The circuit board assembly of claim 5, wherein the central area of the upper part is thinner compared to the edge area of the hold-down device.

8. The circuit board assembly of claim 3, wherein the upper part of the hold-down device has individual spring elements attached to or integrated into a plate of the upper part of the hold-down device, and
wherein the individual spring elements provide a spring effect in a direction of the lower part of the hold-down device.

9. The circuit board assembly of claim 2, wherein the lower part of the hold-down device is resilient.

10. The circuit board assembly of claim 9, wherein spring elements are attached to or formed in receiving openings of the lower part of the hold-down device and rest resiliently against the upper part of the hold-down device.

11. The circuit board assembly of claim 2, wherein the hold-down device further comprises separate spring elements arranged between the upper part of the hold-down device and the lower part of the hold-down device, and
wherein the separate spring elements exert a relative force that presses the lower part of the hold-down device against the circuit board.

12. The circuit board assembly of claim 11, wherein the separate spring elements are arranged in receiving openings in the lower part of the hold-down device and/or in receiving openings in the upper part of the hold-down device.

13. The circuit board assembly of claim 2, wherein the lower part of the hold-down device is segmented and has segments that have a different thickness and/or a different material compared to other areas of the lower part of the hold-down device.

14. The circuit board assembly of claim 13, wherein at least some of the at least one electrical component arranged on the underside of the circuit board are each assigned a separate segment of the segments of the lower part of the hold-down device, and
wherein each separate segment of the segments of the lower part of the hold-down device is adjacent to a respective area on the upper side of the circuit board opposite a respective area on the underside of the circuit board on which a respective electrical component is located.

15. The circuit board assembly of claim 13,
wherein spring elements are attached to or formed in receiving openings of the lower part of the hold-down device and rest resiliently against the upper part of the hold-down device, and
wherein the receiving openings are filled with the insulating material configured to provide a spring force via material properties of the insulating material and/or a geometry of the insulating material

16. The circuit board assembly of claim 15, wherein the receiving openings extend over an entire thickness of the lower part of the hold-down device.

17. The circuit board assembly of claim 13, wherein the hold-down device further comprises separate spring elements arranged between the upper part of the hold-down device and the lower part of the hold-down device,
wherein the separate spring elements exert a relative force that presses the lower part of the hold-down device against the circuit board,
wherein the segments of the lower part of the hold-down device each form an upward-facing receiving opening, and
wherein the separate spring elements are arranged in the upward-facing receiving openings of the segments.

18. The circuit board assembly of claim 1, wherein spring elements of the hold-down device are provided as spring constructions and/or by elastic properties of a material used.

19. The circuit board assembly of claim 18, wherein the spring elements comprise disk springs.

20. The circuit board assembly claim 2, wherein the upper part of the hold-down device comprises a metal.
